(19) United States
(12) Patent Application Publication
(10) Pub. No.: US 2026/0212922 A1
(43) Pub. Date: Jul. 23, 2026

(54) VOLTAGE-DEPENDENT DYNAMIC READ/WRITE ASSIST

(71) Applicant: Xilinx, Inc., San Jose, CA (US)

(72) Inventor: Santosh Yachareni, Hyderabad (IN)

(21) Appl. No.: 18/979,252

(22) Filed: Dec. 12, 2024

(51) Int. Cl. G11C 11/419

(52) U.S. Cl. CPC G11C 11/419

(57) ABSTRACT

An adaptive voltage assist circuit includes a voltage comparison circuit with a first input configured to receive a supply voltage, and a second input configured to receive a threshold voltage. The supply voltage may be configured to be changed dynamically. The voltage comparison circuit is configured to generate at least one output signal indicating whether the supply voltage is above the threshold voltage. An assist logic circuit is configured to use the at least one output signal to generate a control signal indicating a voltage assist configuration for a memory circuit, such as read assist and/or write assist configurations. The memory circuit may be a volatile memory circuit, such as a static random-access memory (SRAM) circuit. The adaptive voltage circuit may be included in an integrated circuit that includes the memory circuit and additional circuits that operate using the supply voltage.

### TECHNICAL FIELD

The present invention relates generally to electronic circuits, and, in particular implementations, to static random-access memory (SRAM).

### BACKGROUND

Adaptive voltage techniques are used in a variety of contexts in electronic circuits, such as integrated circuits, to control the actual value of one or more voltages (e.g., a supply voltage). For example, adaptive voltage techniques may be used to select the best power option in a given system without compromising performance and/or speed. That is, power efficiency may be improved by selecting the best voltages in a system using adaptive voltage techniques while still achieving the desired performance characteristics.

A voltage regulator module (VRM) may be responsible for generating supply voltage(s) within a digital computing system and a may include an input that can modify the supply voltage according to the desire of the user. One example of an adaptive voltage technique is voltage identification (VID). For example, a VRM may receive a VID signal (e.g., a multibit digital signal) that controls the level of the supply voltage output by the VRM. Another example of an adaptive voltage technique is dynamic voltage scaling, which may be implemented as part of a more general dynamic scaling framework: dynamic voltage and frequency scaling (DVFS). The voltage scaling aspect of DVFS may work in a similar manner as VID, where the supply voltage(s) output by a voltage regulator, such as a VRM, are controlled by a DVFS signal.

A variety of circuit blocks (i.e., IP blocks) are often included in a digital computing system, each designed to have specific functionality and operate within a certain range of operating parameters. A VRM is one example of a circuit block. Another example of a circuit block that may be included (and repeated) within many different contexts is a memory circuit. There are two main types of memory: volatile memory (which requires power to maintain data values), and non-volatile memory (that maintains data values for a significant amount of time after power is removed). Volatile memory can require periodic data refreshing, as with dynamic random-access memory (DRAM) or can be designed to not require any refreshing as long as power is maintained as with static random-access memory (SRAM).

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example adaptive voltage assist (AVA) circuit that includes an on-chip voltage comparison circuit and an assist logic circuit configured to generate control signaling indicating a voltage assist configuration for a memory circuit according to output signaling of the voltage comparison circuit in accordance with implementations of the invention;

FIG. 2 illustrates an integrated circuit that includes an AVA circuit and voltage assist circuit coupled between the AVA circuit and a memory circuit, the voltage assist circuit being configured to dynamically control assist voltages for the memory circuit according to control signaling generated by the AVA circuit in accordance with implementations of the invention;

FIG. 3 illustrates a digital computing system that includes an AVA circuit, a voltage assist circuit coupled between the AVA circuit and a memory circuit, and a voltage regulator circuit configured to generate a supply voltage according to a voltage configuration signal, the AVA circuit being configured to generate control signaling indicating whether the supply voltage is greater than a threshold voltage and the voltage assist circuit being configured to dynamically control assist voltages for the memory circuit according to the control signaling in accordance with implementations of the invention;

FIG. 4 illustrates a specific example of an AVA circuit that includes a voltage generation circuit configured to generate four threshold voltages at output nodes, a voltage comparison circuit with four comparators, each with a positive input coupled to a supply voltage and a negative input coupled a respective threshold voltage, and an assist logic circuit configured to generate control signaling indicating a voltage assist configuration for a memory circuit according to output signaling of the voltage comparison circuit in accordance with implementations of the invention;

FIG. 5 illustrates an example digital computing system comprising a voltage regulator circuit, an AVA circuit, and a memory circuit comprising single port SRAM memory cells in accordance with implementations of the invention; and

FIG. 6 illustrates an example digital computing system comprising a voltage regulator circuit, an AVA circuit, and a memory circuit comprising dual port SRAM memory cells in accordance with implementations of the invention.

Corresponding numerals and symbols in the different figures generally refer to corresponding parts unless otherwise indicated. The figures are drawn to clearly illustrate the relevant aspects of the implementations and are not necessarily drawn to scale. The edges of features drawn in the figures do not necessarily indicate the termination of the extent of the feature.

### DETAILED DESCRIPTION OF ILLUSTRATIVE IMPLEMENTATIONS

The making and using of various implementations are discussed in detail below. It should be appreciated, however, that the various implementations described herein are applicable in a wide variety of specific contexts. The specific implementations discussed are merely illustrative of specific ways to make and use various implementations, and should not be construed in a limited scope.

Reference to “an implementation,” “one implementation,” “an implementation,” or “one implementation” in the framework of the present description is intended to indicate that a particular configuration, structure, or characteristic described in relation to the implementation. Hence, phrases such as “in one implementation” or “in one implementation” that may be present in one or more points of the present description do not necessarily refer to one and the same implementation. Moreover, particular conformations, structures, or characteristics may be combined in any adequate way in one or more implementations. The references used herein are provided merely for convenience and do not define the extent of protection or the scope of the implementations.

Adaptive voltage techniques, such as VID or DVFS, are widely used in the industry to select the best power option in a digital computing system without compromising performance and/or speed. Since circuit blocks, such as memory circuits, are designed to be included in systems that generate supply voltage from other circuit blocks (such as a VRM), the memory circuits are designed to be externally powered and compatible with a certain voltage or range of voltages. When adaptive voltage techniques are implemented in a system, the memory circuits must be configured to be operational over the range of voltages.

However, sufficiently extreme voltages (e.g., supply voltages that are used by the memory circuit that are too far from the operational values to support reliable memory operations, such as read and write operations) can cause problems accessing data stored in memory cells, such as during read or write operations. Voltage assist techniques may be used to maintain data integrity during access operations of a memory circuit. For example, when the supply voltage to the memory circuit is too low, a read assist technique may be utilized that modifies one or more of the voltages (e.g., increases the magnitude) of the memory circuit during a read operation to maintain data integrity during the read operation. Similarly, one or more voltages of the memory circuit may also be modified during the write operation, which may be the same or different voltages as during the read operation.

Adaptive voltage techniques, such as VID or DVFS, can conflict with voltage assist techniques. For example, if it is known that the dynamic voltage range of a system using adaptive voltage techniques extends past certain thresholds (e.g., extends too low), then read assist and/or write assist may be required to maintain functionality of the memory circuit under all use cases. This creates potential limitations on both the dynamic voltage range of the system and the configuration of the memory circuit. For example, keeping the write assist circuit and the read assist circuit on at higher voltage ranges may come at the expense of a significant increase in dynamic power consumption, which may be a limitation.

As one example use case, a user may desire to lower the system voltage (e.g., supply voltage for both digital logic circuit blocks and memory circuit blocks) to save power. However, voltage assist techniques, such as read assist and write assist for memory circuits (e.g., SRAM memory circuit blocks), are conventionally set as either on or off and cannot be changed once they are set. Moreover, voltage assist techniques typically cause the system to consume more power. Therefore, the dynamic voltage range of an adaptive voltage technique can be limited by the voltage requirements of the memory circuits since triggering enabling of voltage assist techniques will cause the system to be less power efficient even at higher supply voltages. On the other hand, at lower voltages where voltage assist is required, the net power consumption of the system may be more efficient because other circuit blocks (e.g., digital logic blocks) are more efficient even though the memory circuit blocks may be less efficient.

SRAM compilers are used to generate memory circuits (i.e., IP blocks) that are designed to operate in a given context, such as a specific system with other IP blocks and certain desired overall functionality. VID control can conflict with the read assist and write assist techniques that are used in SRAM compilers, because the compilers may require read and/or write assist to be enabled for systems where VID (and other adaptive voltage techniques) present, even when much of the possible voltage range does not require the voltage assist techniques. Specific read assist and write assist settings may be set using specific bits in the SRAM compiler, such as settings for high power voltage (VHP), medium power voltage (VMP), and low power voltage (VLP). However, once these bits are set, they cannot be changed. That is, even if the supply voltage is moved into a range where read assist and/or write assist is not needed, VID does not turn off the voltage assist. As a result, the best power versus functionality is not obtained.

As an example, suppose a certain supply voltage (e.g., a chip-level voltage, such as VDD) in given system is set to 0.6 V. Both read assist and write assist may need to be enabled at 0.6 V for memory circuits in the system, which may increase the power overhead by an undesirably significant margin (e.g., about 15% or more in some cases). The ability of the memory circuits to function at 0.6 V is therefore coming at the expense of increased power usage (e.g., about 10%-20%, although this may vary). However, it may be that read assist and write assist are not required at or higher than 0.7 V. Consequently, the memory circuits, (e.g., SRAM blocks) may consume more power at 0.6 V because read assist and write assist are enabled than at 0.7 V and higher when read assist and write assist are disabled (i.e., read and write assist could be disabled to improve power efficiency without compromising the functionality).

Yet, as previously discussed, the read assist and write assist bits cannot be changed dynamically, when an adaptive voltage assist technique, such as VID or DVFS, changes the voltage. Therefore, although voltage assist techniques, such as write assist, may not be needed at 0.7 V, they are still enabled to maintain functionality of the memory circuits if the voltage is dynamically changed to 0.6 V.

It is therefore a drawback of conventional systems and methods that the interplay between read assist and write assist settings and adaptive voltage techniques are not considered. As a result, there are currently no existing solutions that provide access to the best power versus functionality trade-offs in systems that use both adaptive voltage techniques (like VID control) and voltage assist techniques for memory circuits (like read assist/write assist). Therefore, improved systems and methods that combine the advantages of voltage assist techniques with the advantages of adaptative voltage techniques are desirable.

The proposed system and methods described herein may have the advantage of accurately controlling read assist and write assist without compromising the functionality of the SRAMS while also getting the best power option at the chip level. This is achieved using an adaptive approach where voltage assist bits, such as read assist and write assist bits, are dynamically implemented and or modified according to measured voltages levels on-chip. In various implementations, an AVA circuit (adaptive voltage assist circuit) includes a voltage comparison circuit and an assist logic circuit. The voltage comparison circuit is configured to generate an output indicating whether a dynamic supply voltage is above a threshold voltage while the assist logic circuit is configured to use the output of the voltage comparison circuit to generate a control signal indicating a voltage assist configuration for a memory circuit.

The AVA circuit may be included in a system that includes one or more memory circuits (e.g., SRAM) that use voltage assist techniques, such as read assist and/or write assist. For example, the supply voltage may be a chip-level voltage (e.g., a core voltage) of an integrated circuit, such as a processor, a field-programmable gate array (FPGA), and others. The system may include a voltage regulator circuit (e.g., a voltage regulator module that may be separate or included as part of an integrated circuit that includes the AVA circuit and the one or more memory circuits.

The proposed adaptive voltage assist circuit may advantageously allow dynamic voltage control (e.g., VID control) to be easily implemented without compromising on the functionality of SRAM. Specifically, when read assist and write assist techniques are desired or required, the proposed adaptive voltage assist circuits may provide the advantage of allowing dynamic voltage control that is compatible with the read assist and write assist settings. For example, the proposed adaptive voltage assist circuits may enable the selection of the best yield versus performance versus functionality trade-offs when system voltage levels are changed that would not be otherwise possible. In this way, the best power savings for all the SRAMs of a system may be obtained at a holistic level.

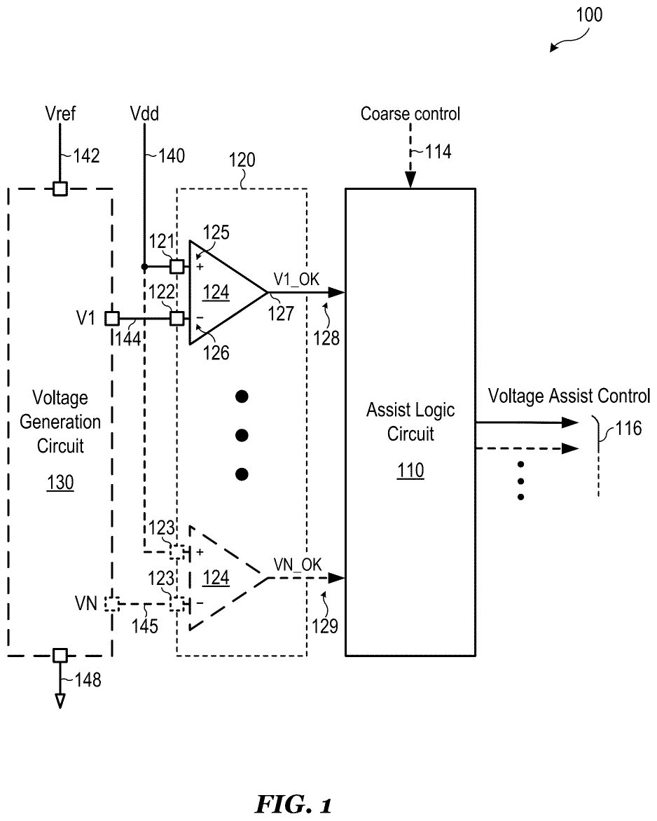

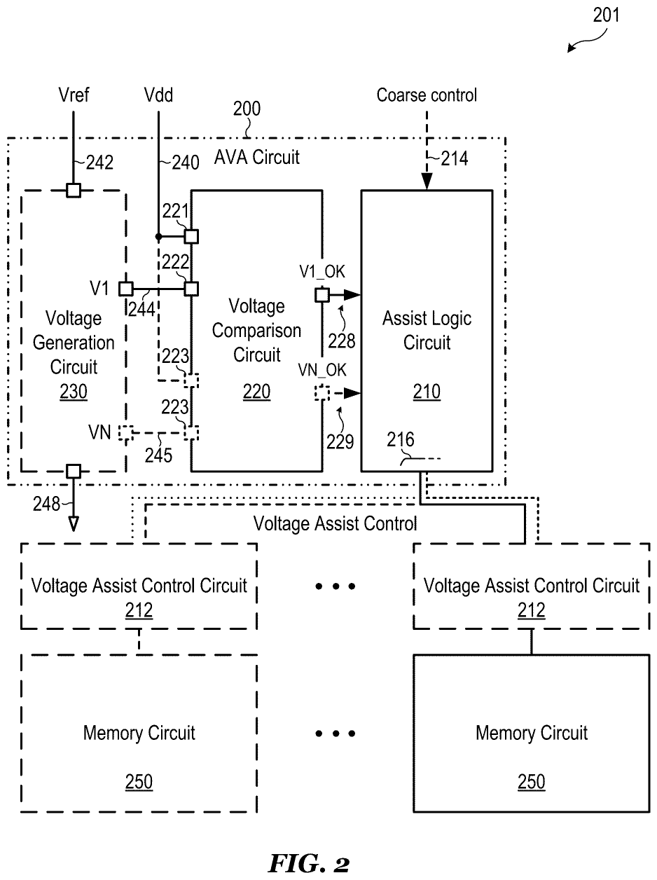

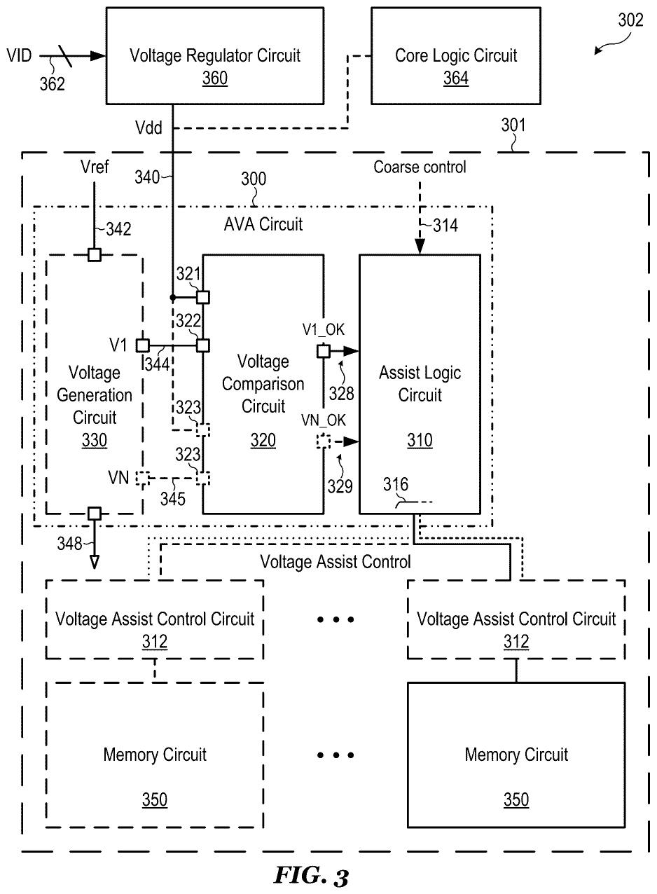

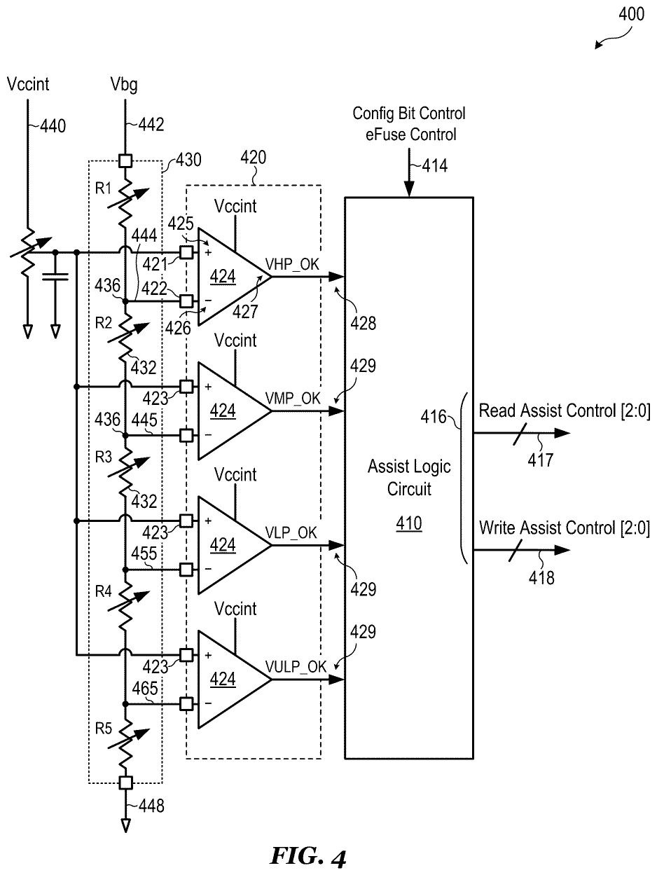

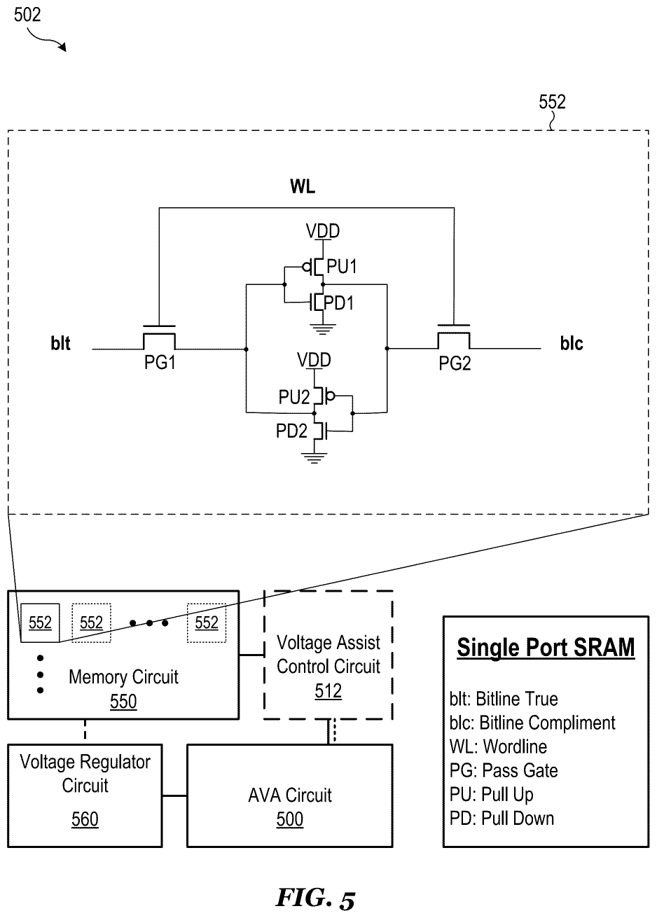

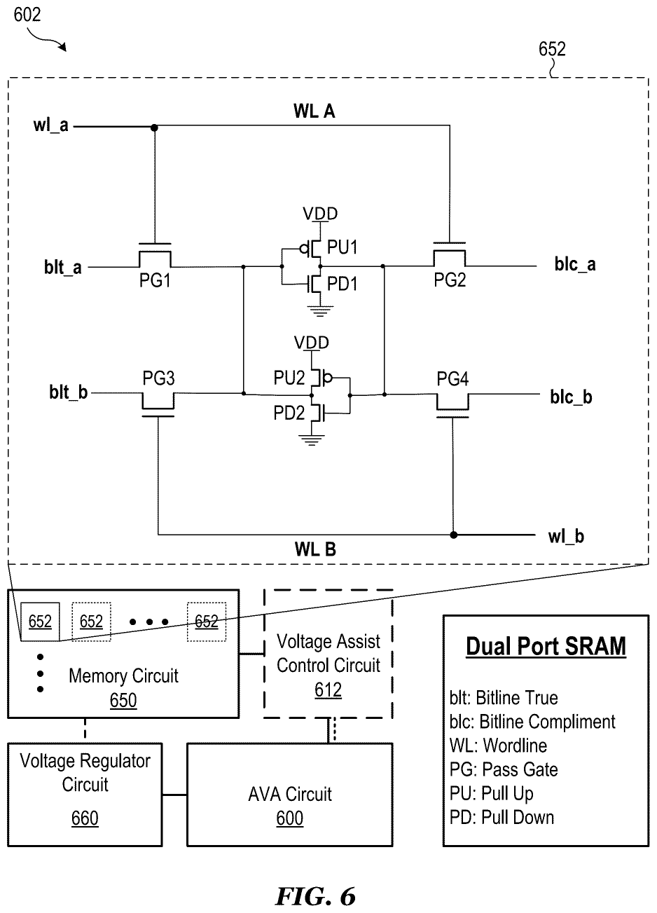

Implementations provided below describe various AVA circuits, and in particular, AVA circuits that are configured to generate control signaling indicating whether a dynamic supply voltage is greater than a threshold voltage. The following description describes the implementations. FIG. 1 is used to describe an example AVA circuit. An example integrated circuit that includes an AVA circuit and a memory circuit is described using FIG. 2. A digital computing system that includes a voltage regulator circuit, an AVA circuit, and a memory circuit is described using FIG. 3. A specific example of an AVA circuit is described using FIG. 4. Two more example digital computing systems are described using FIGS. 5 and 6.

FIG. 1 illustrates an example AVA circuit that includes a voltage comparison circuit and an assist logic circuit configured to generate control signaling indicating a voltage assist configuration for a memory circuit according to output signaling of the voltage comparison circuit in accordance with implementations of the invention.

Referring to FIG. 1, an AVA circuit 100 includes a voltage comparison circuit 120 configured to compare a supply voltage 140 received at a first input 121 to a threshold voltage 144 received at a second input 122 and generate an output signal 128 indicating whether the supply voltage 140 is greater than the threshold voltage 144. The output signal 128 is received by an assist logic circuit 110 that is configured to generate a voltage assist control signal 116 according to the output signal 128 (i.e., based on the relationship between the supply voltage 140, and the threshold voltage 144, which may change dynamically due to adaptive voltage control techniques, such as VID control).

The AVA circuit 100 may also include a voltage generation circuit 130 configured to generate the threshold voltage 144 from a reference voltage 142. For example, the voltage generation circuit 130 may be coupled between the reference voltage 142 and a ground voltage 148. The voltage generation circuit 130 may also be configured to generate one or more additional threshold voltages 145 (e.g., voltage(s) that are different from the threshold voltage 144 and are between the reference voltage 142 and the ground voltage 148). When the voltage generation circuit 130 generates additional threshold voltages, the voltage comparison circuit 120 may include two or more additional inputs 123 configured to compare the one or more additional threshold voltages 145 to the supply voltage 140 and generate corresponding one or more additional outputs 129.

The implementation of the voltage comparison circuit 120 may vary according to the specific details of a given application. In one example implementation, the voltage comparison circuit 120 includes a comparator 124 (e.g., one comparator for each of the threshold voltages received by the voltage comparison circuit 120). The voltage comparison circuit 120 includes a positive input 125 and a negative input 126 that are compared to generate a comparator output 127, which in this case is a binary digital output that is “1” (logical high voltage) when the positive input 125 is greater than the negative input 126 and is “0” (logical low voltage) when the positive input 125 is less than the negative input 126.

Each of N threshold voltages may be labeled as V1 to VN as shown, with a comparator included in the voltage comparison circuit 120 for each (N comparators). The N comparators then generated N output signals. In implementations where the supply voltage 140 is provided at the positive input 125 (as shown), the output signal 128 and the one or more additional outputs 129 may be interpreted as indicating whether the supply voltage 140 is “OK”, or higher than some known target range, hence the labeling of the output signals as V1_OK to VN_OK.

The assist logic circuit 110 uses the output signal 128 and the one or more additional outputs 129 (when included) to generate the voltage assist control signal 116 indicating an appropriate voltage assist configuration. For example, the voltage assist control signal 116 may be configuration settings for a read assist and a write assist for a memory circuit, such as an SRAM circuit. In a simple implementation, the voltage assist control signal 116 may be a single bit (e.g., an enable bit) for each included voltage assist techniques. In other implementations, the voltage assist control signal 116 may include multiple bits for one or more of the voltage assist techniques, such as to indicate different voltage levels for each of the voltage assist techniques.

The assist logic circuit 110 may also include and use other configuration inputs. In one implementation, the assist logic circuit 110 includes a coarse configuration signal 114. In one example implementation, the coarse configuration signal 114 comprises eFuse configuration bits. Of course, other input signals (configuration and otherwise) may be included and used by the assist logic circuit 110 to determine the appropriate voltage assist configuration settings and generate the voltage assist control signal 116.

The assist logic circuit 110 may include various digital logic components arranged in a configuration that may be based on the specific details of a given application. Some examples of digital logic components include logic gates (e.g., AND gates, OR gates, NAND gates, NOR gates etc.), inverters, buffers, flip-flops, latches, and others. In one implementation, the assist logic circuit 110 consists of combinational logic (i.e., not including sequential logic that allow storage of information, such as flip-flops, or memory circuitry). However, in other implementations, sequential logic and/or memory (such as a lookup table) may be included in the assist logic circuit 110. For example, the assist logic circuit 110 may include logic gates that receive the output signal 128, the one or more additional outputs 129, (when included), and the coarse control signal 114 (when included) as inputs and output the voltage assist control signal 116 according to the result of the voltage comparison circuit 120. Such an arrangement of logic gates may function as a decoder circuit that provides specific desired voltage assist control signal 116 outputs for the possible combinations of inputs (e.g., output signal 128, the one or more additional outputs 129, and/or the coarse control signal 114).

The AVA circuit 100 may have the advantage of being required only once per system (e.g., once per chip). For example, the assist logic circuit 110 may be centrally placed in an integrated circuit (chip) that includes other circuits, such as core logic, along with multiple memory circuits (e.g., multiple SRAM blocks) implementing voltage assist techniques like read assist and write assist that are controlled by the voltage assist control signal 116 generated by the single AVA circuit 100. The comparator(s), along with the logic to enable/disable voltage assist techniques with a few bits (e.g., 4-5 bits of configuration controller may allow the system to automatically enable and disable voltage assist techniques when the supply voltage 140 is at certain voltage levels (e.g., determined by the threshold voltages) with the additional benefit of being relatively small. Further, the AVA circuit 100 may have the advantage of simplicity, which may allow the AVA circuit 100 to be incorporated easily into systems where it is desirable to use both adaptive voltage techniques and voltage assist techniques for included memory circuits.

FIG. 2 illustrates an integrated circuit that includes an AVA circuit and voltage assist circuit coupled between the AVA circuit and a memory circuit, the voltage assist circuit being configured to dynamically control assist voltages for the memory circuit according to control signaling generated by the AVA circuit in accordance with implementations of the invention. The AVA circuit included in the integrated circuit of FIG. 2 may be similar to other AVA circuits described herein such as the AVA circuit of FIG. 1, for example. Similarly labeled elements may be as previously described.

Referring to FIG. 2, an AVA circuit 200 is included in an integrated circuit 201 that also includes memory circuit 250, such as an SRAM circuit. It should be noted that here and in the following a convention has been adopted for brevity and clarity wherein elements adhering to the pattern [x00] where ‘x’ is the figure number may be related implementations of an AVA circuit in various implementations. For example, the AVA circuit 200 may be similar to the AVA circuit 100 except as otherwise stated. An analogous convention has also been adopted for other elements as made clear by the use of similar terms in conjunction with the aforementioned numbering system.

The AVA circuit 200 includes a voltage comparison circuit 220 configured to compare a supply voltage 240 received at a first input 221 to a threshold voltage 244 received at a second input 222 and generate an output signal 228 indicating whether the supply voltage 240 is greater than the threshold voltage 244 The voltage comparison circuit 220 may also receive one or more additional threshold voltages 245 at two or more additional inputs 223 and generate one or more additional outputs 229 indicating whether the supply voltage 240 is greater than the one or more additional threshold voltages 245.

The output signal 228 (and the one or more additional outputs 229, when included) is received by an assist logic circuit 210 that is configured to generate a voltage assist control signal 216. The assist logic circuit 210 may also receive other configuration signals (e.g., configuration bits), such as the coarse configuration signal 214, which may include eFuse configuration bits, for example. The AVA circuit 200 may also include a voltage generation circuit 230 (e.g., coupled between the reference voltage 242 and a ground voltage 248) configured to generate the threshold voltage 244 from a reference voltage 242. The voltage generation circuit 230 may also be configured to generate one or more additional threshold voltages 245.

Although it is possible for the integrated circuit 201 to only include a single memory circuit 250, the integrated circuit 201 includes multiple memory circuit blocks (e.g., duplicates of the memory circuit 250 and/or different memory circuits in some implementations). A voltage assist control circuit 212 may be included for the memory circuit 250 that is configured to perform the voltage assist techniques (such as read assist or write assist) according to the configuration dynamically indicated by the voltage assist control signal 216. While in this example, the voltage assist control circuit 212 is shown as being present for each memory circuit 250, fewer or a single voltage assist control circuit 212 may be included with multiple memory circuits in some implementations.

FIG. 3 illustrates a digital computing system that includes an AVA circuit, a voltage assist circuit coupled between the AVA circuit and a memory circuit, and a voltage regulator circuit configured to generate a supply voltage according to a voltage configuration signal, the AVA circuit being configured to generate control signaling indicating whether the supply voltage is greater than a threshold voltage and the voltage assist circuit being configured to dynamically control assist voltages for the memory circuit according to the control signaling in accordance with implementations of the invention. The AVA circuit included in the digital computing system of FIG. 3 may be similar to other AVA circuits described herein such as the AVA circuit of FIG. 1, for example. Similarly labeled elements may be as previously described.

Referring to FIG. 3, an AVA circuit 300 is included in an integrated circuit 301 of a digital computing system 302 that also includes memory circuit 350, such as an SRAM circuit. The digital computing system 302 also includes a voltage regulator circuit 360 that is configured to generate a supply voltage 340 according to a voltage configuration signal 362 (e.g., a VID control signal). The voltage regulator circuit 360 may be implemented in any suitable way, including separately from the integrated circuit 301 or as part of the integrated circuit 301. In various implementations, the voltage regulator circuit 360 is an integrated implementation of a VRM, such as an integrated voltage regulator (IVR). The supply voltage 340 may be used to power both the memory circuit 350 and other circuits, such as a core logic circuit 364.

The AVA circuit 300 includes a voltage comparison circuit 320 configured to compare the supply voltage 340 received at a first input 321 to a threshold voltage 344 received at a second input 322 and generate an output signal 328 indicating whether the supply voltage 340 is greater than the threshold voltage 344 The voltage comparison circuit 320 may also receive one or more additional threshold voltages 345 at two or more additional inputs 323 and generate one or more additional outputs 329 indicating whether the supply voltage 340 is greater than the one or more additional threshold voltages 345.

The output signal 328 (and the one or more additional outputs 329, when included) is received by an assist logic circuit 310 that is configured to generate a voltage assist control signal 316 that is configured to dynamically control voltage assist techniques, such as a voltage assist control circuit 312. The assist logic circuit 310 may also receive other configuration signals (e.g., configuration bits), such as the coarse configuration signal 314, which may include eFuse configuration bits, for example. The AVA circuit 300 may also include a voltage generation circuit 330 (e.g., coupled between the reference voltage 342 and a ground voltage 348) configured to generate the threshold voltage 344 from a reference voltage 342. The voltage generation circuit 330 may also be configured to generate one or more additional threshold voltages 345.

FIG. 4 illustrates a specific example of an AVA circuit that includes a voltage generation circuit configured to generate four threshold voltages at output nodes, a voltage comparison circuit with four comparators, each with a positive input coupled to a supply voltage and a negative input coupled a respective threshold voltage, and an assist logic circuit configured to generate control signaling indicating a voltage assist configuration for a memory circuit according to output signaling of the voltage comparison circuit in accordance with implementations of the invention. The AVA circuit of FIG. 1 is a specific implementation of other AVA circuits described herein such as the AVA circuit of FIG. 1, for example. Similarly labeled elements may be as previously described.

Referring to FIG. 4, an AVA circuit 400 includes a voltage comparison circuit 420 configured to compare a supply voltage 440 (labeled here as Vccint, and which may be a core voltage) received at a first input 421 to a threshold voltage 444 (labeled as Vbg here) received at a second input 422 and generate an output signal 428 indicating whether the supply voltage 440 is greater than the threshold voltage 444. The output signal 428 is received by an assist logic circuit 410 that is configured to generate a voltage assist control signal 416 according to the output signal 428 (i.e., based on the relationship between the supply voltage 440, and the threshold voltage 444, which may change dynamically due to adaptive voltage control techniques, such as VID control).

In this specific example, the AVA circuit 400 includes a voltage generation circuit 430 implemented as several voltage dividers configured to generate the four threshold voltages (a threshold voltage 444 and three additional threshold voltages 445, which here will be referred to as VHP, VMP, VLP, and VULP) from a reference voltage 442. The voltage generation circuit 430 is coupled between the reference voltage 442 and a ground voltage 448. The voltage divider circuits include variable resistors 432 (R1, R2, R3, R4, and R5) with output nodes 436 interspersed therebetween.

For example, the four threshold voltages VHP, VMP, VLP, and VULP may be four voltage levels (e.g., high power voltage, medium power voltage, low power voltage, ultra-low power voltage) that are identified as being significant for memory circuits that will be controlled using the voltage assist control signal 416, which here includes a read assist control signal 417 (3-bits) and a write assist control signal 418 (also 3-bits). Of course, the read assist control signal 417 and the write assist control signal 418 may also have more bits or fewer bits and may also be different from one another.

The voltage comparison circuit 420 includes additional inputs 423 for each of the additional threshold voltages 445, 455, 465 configured to compare the additional threshold voltages 445, 455, 465 to the supply voltage 440 and generate corresponding additional outputs 429. The voltage comparison circuit 420 is implemented in this example with a comparator 424 for each of the threshold voltage 444 and the three additional threshold voltages 445, 455, 465. Each comparator 424 includes a positive input 425 configured to receive the supply voltage 440, a negative input 426 configured to receive a respective threshold voltage, and a comparator output 427 configured to output an output signal. As shown, the output signal 428 and the three additional outputs 429 are labeled VHP_OK, VMP_OK, VLP_OK, and VULP_OK in this implementation.

The assist logic circuit 410 uses the output signal 428 and the additional outputs 429 to generate the voltage assist control signal 416 including the read assist control signal 417 and the write assist control signal 418 to indicate an appropriate read assist configuration and an appropriate write assist configuration. In this specific example, the assist logic circuit 410 also includes a coarse configuration signal 414 which includes config bit control and eFuse control.

FIG. 5 illustrates an example digital computing system comprising a voltage regulator circuit, an AVA circuit, and a memory circuit comprising single port SRAM memory cells in accordance with implementations of the invention. The digital computing system of FIG. 5 may be a specific implementation of other digital computing systems described herein such as the digital computing system of FIG. 3, for example. Similarly labeled elements may be as previously described.

Referring to FIG. 5, a digital computing system 502 includes an AVA circuit 500 and a memory circuit 550 (which may both be implemented as an integrated circuit, for example). In various implementations. the digital computing system 502 is a processor and is an FPGA in one implementation. In some implementations, the memory circuit 550 is a volatile memory circuit, and is an SRAM in one implementation. The digital computing system 502 further includes a voltage regulator circuit 560 and may include a voltage assist control circuit 512 (e.g., one or fewer for each memory circuit 550 included in the digital computing system 502). The memory circuit 550 includes at least one memory cell 552 (e.g., a memory cell array).

In this specific example, each memory cell 552 is implemented as a single port SRAM memory cell, as shown. There are six transistors (PU1, PU2, PD1, PD2, PG1, and PG2) per cell, coupled to a corresponding bit line (blt/blc) and word line (WL). Voltage assist techniques, such as read assist and write assist, may be used with the memory circuit 550 implemented as an array of single port SRAM memory cells and a voltage assist control signal generated by the AVA circuit 500 may be used to dynamically control the read assist and write assist based on a supply voltage configured to be dynamically changed by the voltage regulator circuit 560.

Specifically, the voltage regulator circuit 560 may provide the dynamic supply voltage to power to the memory circuit 550. The AVA circuit 500 may receive the dynamic supply voltage and generate the voltage assist control signal according to (based on) the current level of the dynamic supply voltage. For example, as discussed in the foregoing, one or more of voltage assist techniques may not be needed/desired when the supply voltage to the memory 550 is above certain threshold. The voltage assist control signal may used (e.g., provided to the voltage assist control circuit 512) to enable/disable certain voltage assist techniques dynamically as the supply voltage is dynamically changed.

FIG. 6 illustrates an example digital computing system comprising a voltage regulator circuit, an AVA circuit, and a memory circuit comprising dual port SRAM memory cells in accordance with implementations of the invention. The digital computing system of FIG. 6 may be a specific implementation of other digital computing systems described herein such as the digital computing system of FIG. 3, for example. Similarly labeled elements may be as previously described.

Referring to FIG. 6, a digital computing system 602 includes an AVA circuit 600 and a memory circuit 650 (which may both be implemented as an integrated circuit, for example). In various implementations. the digital computing system 602 is a processor and is an FPGA in one implementation. In some implementations, the memory circuit 650 is a volatile memory circuit, and is an SRAM in one implementation. The digital computing system 602 further includes a voltage regulator circuit 660 and may include a voltage assist control circuit 612 (e.g., one or fewer for each memory circuit 650 included in the digital computing system 602). The memory circuit 650 includes at least one memory cell 652 (e.g., a memory cell array).

In this specific example, each memory cell 652 is implemented as a dual port SRAM memory cell, as shown. There are eight transistors (PU1, PU2, PD1, PD2, PG1, PG2, PG3, and PG4) per cell, coupled to a corresponding bit lines (blt_a/blc_a and blt_a/blc_a) and word lines (wl_a and wl_b). Voltage assist techniques, such as read assist and write assist, may be used with the memory circuit 650 implemented as an array of dual port SRAM memory cells and a voltage assist control signal generated by the AVA circuit 600 may be used to dynamically control the read assist and write assist based on a supply voltage configured to be dynamically changed by the voltage regulator circuit 660.

While this invention has been described with reference to illustrative implementations, this description is not intended to be construed in a limiting sense. Various modifications and combinations of the illustrative implementations, as well as other implementations of the invention, will be apparent to persons skilled in the art upon reference to the description. It is therefore intended that the appended claims encompass any such modifications or implementations.

What is claimed is:

1. An adaptive voltage assist (AVA) circuit comprising:
a voltage comparison circuit comprising a first input configured to receive a supply voltage, and a second input configured to receive a threshold voltage, the voltage comparison circuit being configured to generate at least one output signal indicating whether the supply voltage is above the threshold voltage; and
an assist logic circuit configured to use the at least one output signal to generate a control signal indicating a voltage assist configuration for a memory circuit.

2. The AVA circuit of claim 1, further comprising:
a voltage generation circuit coupled between a reference voltage and a ground voltage, the voltage generation circuit being configured to generate the threshold voltage and at least one additional threshold voltage from the reference voltage,
the at least one output signal indicating the voltage assist configuration when the supply voltage is above the threshold voltage, and further indicating one or more different voltage assist configurations when the supply voltage is below the threshold voltage and above one or more of the at least one additional threshold voltage.

3. The AVA circuit of claim 2, wherein
the threshold voltage is a high power voltage (VHP) less than the reference voltage, and
the at least one additional threshold voltage consists of a medium power voltage (VMP) less than VHP, a low power voltage (VLP) less than VMP, and an ultra-low power voltage (VULP) less than VLP.

4. The AVA circuit of claim 1, wherein the control signal comprises a read assist control signal indicating a read assist configuration for the memory circuit, and a write assist control signal indicating a write assist configuration for the memory circuit.

5. The AVA circuit of claim 4, wherein
the read assist control signal is an N-bit signal, N being greater than 1, and
the write assist control signal is an M-bit signal, M being greater than 1.

6. The AVA circuit of claim 5, wherein N and M are both equal to three.

7. The AVA circuit of claim 1, wherein the supply voltage is configured to be dynamically adjusted using a voltage identification (VID) signal provided to a voltage regulator circuit generating the supply voltage.

8. The AVA circuit of claim 1, wherein the supply voltage is configured to be dynamically adjusted using a dynamic voltage and frequency scaling (DVFS) signal provided to a voltage regulator circuit generating the supply voltage.

9. The AVA circuit of claim 1, further comprising:
a voltage divider circuit coupled between a reference voltage and a ground voltage, the voltage divider circuit comprising
a first variable resistor coupled between the reference voltage and an output node, and
a second variable resistor coupled between the output node and the ground voltage,
the voltage divider circuit being configured to generate the threshold voltage at the output node,
wherein the voltage comparison circuit comprises a comparator configured to
receive the supply voltage at a positive input,
receive the threshold voltage at a negative input,
output a logical high signal when the positive input is greater than the negative input, and
output a logical low signal when the positive input is less than the negative input.

10. The AVA circuit of claim 1, wherein the assist logic circuit is further configured to use a coarse configuration signal in addition to the at least one output signal to generate the control signal.

11. An integrated circuit comprising:
an adaptive voltage assist (AVA) circuit comprising:
a voltage comparison circuit comprising a first input configured to receive a supply voltage, and a second input configured to receive a threshold voltage, the voltage comparison circuit being configured to generate at least one output signal indicating whether the supply voltage is above the threshold voltage, and
an assist logic circuit configured to use the at least one output signal to generate a control signal;
a memory circuit; and
a voltage assist control circuit coupled between the AVA circuit and the memory circuit, the voltage assist control circuit being configured to dynamically control read and write assist voltages for the memory circuit according to the control signal.

12. The integrated circuit of claim 11, further comprising:
one or more additional memory circuits, each configured to receive dynamically controlled read and write assist voltages according to the control signal generated by the same AVA circuit.

13. The integrated circuit of claim 11, wherein the memory circuit comprises static random-access memory (SRAM).

14. The integrated circuit of claim 11, further comprising:
a voltage generation circuit coupled between a reference voltage and a ground voltage, the voltage generation circuit being configured to generate the threshold voltage and one or more additional threshold voltages from the reference voltage,
the at least one output signal further indicating whether the supply voltage is above the one or more additional threshold voltages.

15. The integrated circuit of claim 11, wherein
the control signal comprises a read assist control signal and a write assist control signal,
the read assist control signal is an N-bit signal, N being greater than 1, and
the write assist control signal is an M-bit signal, M being greater than 1.

16. The integrated circuit of claim 11, further comprising:
a voltage divider circuit coupled between a reference voltage and a ground voltage, the voltage divider circuit comprising
a first variable resistor coupled between the reference voltage and an output node, and
a second variable resistor coupled between the output node and the ground voltage,
the voltage divider circuit being configured to generate the threshold voltage at the output node,
wherein the voltage comparison circuit comprises a comparator configured to
receive the supply voltage at a positive input,
receive the threshold voltage at a negative input,
output a logical high signal when the positive input is greater than the negative input, and
output a logical low signal when the positive input is less than the negative input.

17. A digital computing system comprising:
a core logic circuit configured to operate at a supply voltage;
a plurality of static random-access memory (SRAM) memory blocks configured to operate at the supply voltage; and
an adaptive voltage assist (AVA) circuit comprising:
a voltage comparison circuit comprising a first input configured to receive the supply voltage, and a second input configured to receive a threshold voltage, the voltage comparison circuit being configured to generate at least one output signal indicating whether the supply voltage is above the threshold voltage, and
an assist logic circuit configured to use the at least one output signal to generate a control signal; and
at least one voltage assist control circuit coupled between the AVA circuit and each of the plurality of SRAM memory blocks, the at least one voltage assist control circuit being configured to dynamically control read and write assist voltages for each of the plurality of SRAM memory blocks according to the control signal.

18. The digital computing system of claim 17, wherein the digital computing system is a field-programmable gate array (FPGA) integrated circuit.

19. The digital computing system of claim 17, wherein the assist logic circuit is further configured to use a coarse configuration signal in addition to the at least one output signal to generate the control signal, the coarse configuration signal comprises eFuse configuration bits.

20. The digital computing system of claim 17, further comprising:
a voltage divider circuit coupled between a reference voltage and a ground voltage, the voltage divider circuit comprising
a first variable resistor coupled between the reference voltage and an output node, and
a second variable resistor coupled between the output node and the ground voltage,
the voltage divider circuit being configured to generate the threshold voltage at the output node,
wherein the voltage comparison circuit comprises a comparator configured to
receive the supply voltage at a positive input,
receive the threshold voltage at a negative input,
output a logical high signal when the positive input is greater than the negative input, and
output a logical low signal when the positive input is less than the negative input.
